(19) United States
(12) Patent Application Publication
(10) Pub. No.: US 2026/0238207 A1
(43) Pub. Date: Aug. 13, 2026

(54) DIFFERENTIAL-TO-SINGLE-ENDED ACTIVE CONVERTER

(71) Applicant: QUALCOMM Incorporated, San Diego, CA (US)

(72) Inventors: Ibrahim Ramez CHAMAS, Carlsbad, CA (US); Bhushan Shanti ASURI, San Diego, CA (US)

(21) Appl. No.: 19/049,384

(22) Filed: Feb. 10, 2025

(51) Int. Cl. H03K 17/687; H04B 1/04

(52) U.S. Cl. CPC H03K 17/6872; H04B 1/04

(57) ABSTRACT

Certain aspects of the present disclosure are directed towards apparatus and techniques for differential-to-single-ended signal conversion. An example apparatus generally includes: a first transistor including a first terminal coupled to a first input of a differential input pair of the apparatus and a second terminal coupled to an output node of the apparatus; a second transistor including a second terminal coupled to a second input of the differential input pair and a second terminal coupled to the output node of the apparatus; a third transistor including a first terminal coupled to the first input of the differential input pair; and a fourth transistor including a first terminal coupled to the second input of the differential input pair, a second terminal of the third transistor being coupled to a second terminal of the fourth transistor.

### BACKGROUND

### Field of the Disclosure

Certain aspects of the present disclosure generally relate to electronic components and, more particularly, to circuitry for differential-to-single-ended signal conversion.

### Description of Related Art

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system). Wireless devices may include transmitters for processing signals for transmission via antennas. A transmitter may include one or more balanced-unbalanced (balun) transformers for converting a differential signal to a single-ended signal for amplification.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards an apparatus for differential-to-single-ended signal conversion. The apparatus generally includes: a first transistor including a first terminal coupled to a first input of a differential input pair of the apparatus and a second terminal coupled to an output node of the apparatus; a second transistor including a second terminal coupled to a second input of the differential input pair and a second terminal coupled to the output node of the apparatus; a third transistor including a first terminal coupled to the first input of the differential input pair; and a fourth transistor including a first terminal coupled to the second input of the differential input pair, a second terminal of the third transistor being coupled to a second terminal of the fourth transistor.

Certain aspects of the present disclosure are directed towards a method for differential-to-single-ended signal conversion. The method generally includes receiving a differential signal at a first input of a differential input pair and a second input of the differential input pair and converting the differential signal to a single-ended signal via a balanced-to-unbalanced circuit comprising: a first transistor including a first terminal coupled to the first input of a differential input pair and a second terminal coupled to an output node of the balanced-to-unbalanced circuit; a second transistor including a second terminal coupled to the second input of the differential input pair and a second terminal coupled to the output node of the balanced-to-unbalanced circuit; a third transistor including a first terminal coupled to the first input of the differential input pair; and a fourth transistor including a first terminal coupled to the second input of the differential input pair, a second terminal of the third transistor being coupled to a second terminal of the fourth transistor.

Certain aspects of the present disclosure are directed towards a transmitter comprising a mixer and an active-component balanced-to-unbalanced (balun) circuit coupled to the mixer and including: a first transistor including a first terminal coupled to a first input of a differential input pair of the balun circuit and a second terminal coupled to an output node of the balun circuit; a second transistor including a second terminal coupled to a second input of the differential input pair and a second terminal coupled to the output node of the balun circuit; a third transistor including a first terminal coupled to the first input of the differential input pair; and a fourth transistor including a first terminal coupled to the second input of the differential input pair, a second terminal of the third transistor being coupled to a second terminal of the fourth transistor.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver front end, in accordance with certain aspects of the present disclosure.

FIG. 4 illustrates an example active-component balanced-unbalanced (balun) circuit implemented with transimpedance (Gm) amplifiers, in accordance with certain aspects of the present disclosure.

FIG. 5 illustrates example of unipolar active-component balun configurations, in accordance with certain aspects of the present disclosure.

FIG. 6 illustrates graphs showing a mismatch in input capacitances of positive and negative inputs of a unipolar balun configuration as a function of input voltage, in accordance with certain aspects of the present disclosure.

FIG. 7 illustrates examples of bipolar balun circuits implemented using a combination of active-component balun configurations, in accordance with certain aspects of the present disclosure.

FIG. 8 illustrates a graph showing capacitances at negative inputs of a unipolar balun configuration and a bipolar balun configuration as a function of input voltage, in accordance with certain aspects of the present disclosure.

FIG. 9 illustrates a graph showing capacitances at the positive inputs of a unipolar balun configuration and a bipolar balun configuration as function of input voltage, in accordance with certain aspects of the present disclosure.

FIG. 10 illustrates a graph showing capacitances at positive and negative inputs of a bipolar balun configuration including dummy capacitive elements on the negative input as a function of input voltage, in accordance with certain aspects of the present disclosure.

FIG. 11 illustrates an example balun circuit implemented with linearization elements, in accordance with certain aspects of the present disclosure.

FIG. 12 is a flow diagram illustrating example operations for differential-to-single-ended signal conversion.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects are directed towards an active-component balanced-unbalanced (balun) circuit. The balun circuit may convert a differential signal to a single-ended signal, and may be used to replace one or more inductor- or transformer-based baluns of a transmitter, especially for paths associated with lower frequencies that may use large inductors to implement a balun. In some cases, the active-component balun circuit may be implemented using various candidate combinations of balun configurations described herein. Some balun configurations may be implemented as buffers using transistors. Using the combinations of balun configurations may provide improvements in terms of input impedance balancing and impedance linearity. The balun may be implemented as part of a transceiver of any suitable device such as a user equipment (UE) or a base station.

### Example Wireless Communications

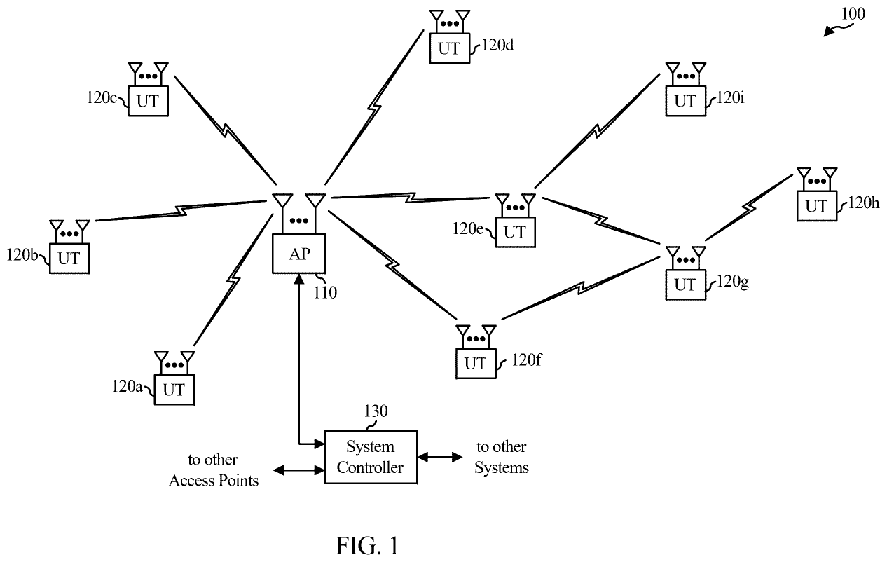

FIG. 1 illustrates a wireless communications system 100 with access points 110 and user terminals 120, in which aspects of the present disclosure may be practiced.
For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported).

In some aspects, the user terminal 120 or access point 110 may include an active-component balun circuit, as described in more detail herein.

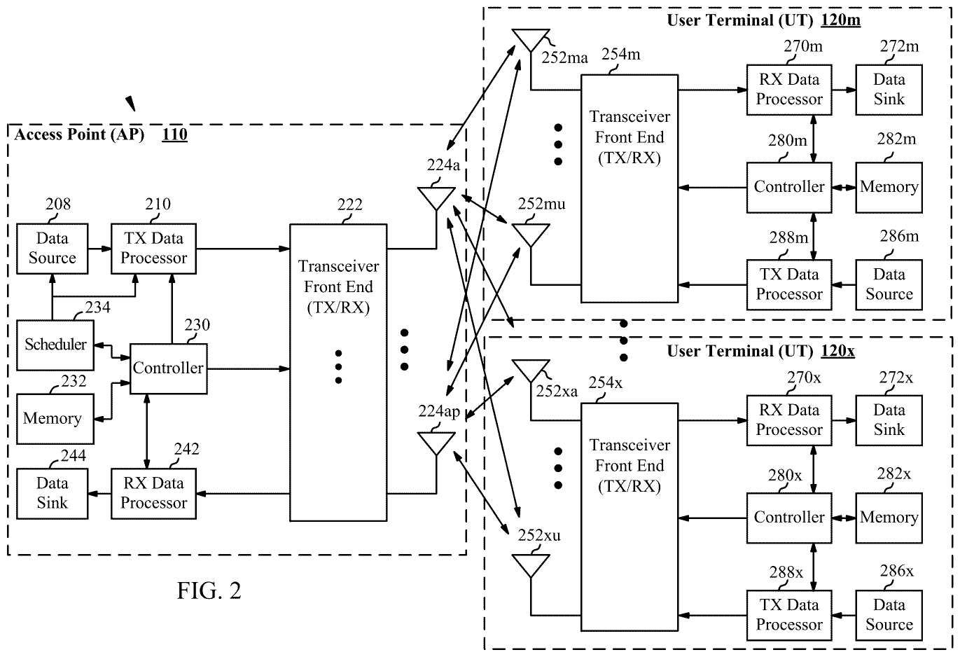

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a transmitter (TX) data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. A receiver (RX) data processor 242 processes (e.g., demodulates, deinterleaves, and decodes) the recovered uplink data symbol stream in accordance with the rate used for that stream to obtain decoded data. The decoded data for each user terminal may be provided to a data sink 244 (e.g., corresponding to data sink 272 of UT) for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

In some aspects, the transceiver front end 254 or 222 may include an active-component balun circuit, as described in more detail herein.

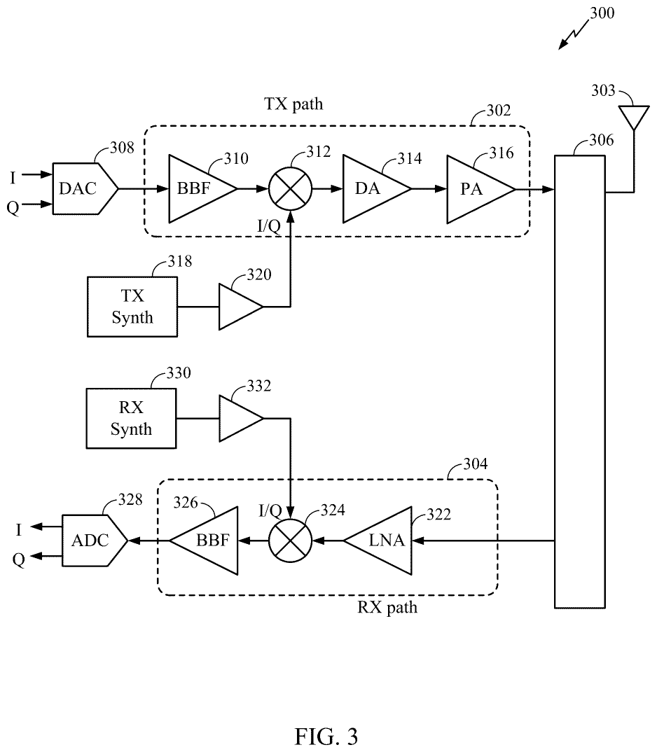

FIG. 3 is a block diagram of an example transceiver front end 300, such as transceiver front ends 222, 254 in FIG. 2, in which aspects of the present disclosure may be practiced. The transceiver front end 300 includes at least one transmit (TX) path 302 (also known as a transmit chain) for transmitting signals via one or more antennas and at least one receive (RX) path 304 (also known as a receive chain) for receiving signals via the one or more antennas. When the TX path 302 and the RX path 304 share an antenna 303, the paths may be connected with the antenna via an interface 306, which may include any of various suitable RF devices, such as a switch, a duplexer, a diplexer, a multiplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, the DA 314, and the PA 316 may be included in a radio frequency integrated circuit (RFIC). In some cases, the PA 316 may be external to the RFIC. In some cases, the DA 314 may include a pre-DA that may drive a DA, where the DA drives the PA 316.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies of the LO frequency and the frequencies of the baseband signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303. While one mixer 312 is illustrated, several mixers may be used to upconvert the filtered baseband signals to one or more intermediate frequencies and to thereafter upconvert the intermediate frequency (IF) signals to a frequency for transmission. In some cases, an active-component balun circuit may be used to convert a differential signal at an output of the mixer 312 to a single-ended signal for amplification via the DA 314 and the PA 316, as described in more detail herein.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (e.g., downconvert). The baseband signals output by the mixer 324 may be filtered by the BBF 326 before being converted by an analog-to-digital converter (ADC) 328 to digital I and/or Q signals for digital signal processing.

Certain transceivers may employ a variable-frequency oscillator (e.g., a voltage-controlled oscillator (VCO) or a digitally controlled oscillator (DCO)) to generate a stable, tunable LO signal with a particular tuning range. Thus, the transmit LO signal may be produced by a TX frequency synthesizer 318, which may be buffered or amplified by amplifier 320 before being mixed with the baseband signals in the mixer 312. Similarly, the receive LO signal may be produced by an RX frequency synthesizer 330, which may be buffered or amplified by amplifier 332 before being mixed with the RF signals in the mixer 324. For certain aspects, a single frequency synthesizer may be used for both the TX path 302 and the RX path 304. In certain aspects, the TX frequency synthesizer 318 and/or RX frequency synthesizer 330 may include a frequency multiplier, such as a frequency doubler, that is driven by an oscillator (e.g., a VCO) in the frequency synthesizer.

While FIGS. 1-3 provide wireless communications as an example application in which certain aspects of the present disclosure may be implemented to facilitate understanding, certain aspects described herein may be used for differential-to-single-ended signal conversion in any of various other suitable systems.

### Example Techniques for Balanced-to-Unbalanced Conversion

Certain aspects of the present disclosure are directed towards techniques for converting between a balanced (e.g., differential) signal and an unbalanced (e.g., single-ended (SE)) signal. Typically, a balanced-unbalanced (balun) component is implemented using an inductor or a transformer to convert a differential signal to an SE signal. On-chip processes such as filtering and upconversion may be performed using differential signals, whereas other operations such as signal amplification using a power amplifier (PA) may be performed using a SE signal. Thus, a balun component is used to interface on-chip differential signal operations with inputs/outputs (I/Os) that provide SE signals for amplification.

The area consumed by the balun may be inversely proportional to the operating frequency of a wireless device. Thus, in lower operating bands, the size of the balun component increases. As operating bands/frequency coverage is expanded in wireless devices, adding more electromagnetic (EM)-based balun components (e.g., inductor- or transformer-based balun components) results in increased area consumption, causing isolation and linear floor-planning issues. In other words, with the analog circuitry of transceivers increasing in area, the fanout of routes becomes challenging to maintain isolation between signals.

Certain aspects of the present disclosure are directed towards an active-component balun circuit to replace one or more inductor- or transformer-based balun components (e.g., passive baluns) of a device. The active-component balun circuit may be implemented with transistors, providing differential-to-SE signal conversion with reduced area consumption. In some aspects, the active-component balun circuit may be implemented such that the differential input of the balun (e.g., positive (P) and minus (M) terminals of the balun circuit, also referred to herein as positive and negative input nodes) are balanced (e.g., have equal impedance). The active-component balun circuit may be implemented with high linearity to mimic the typical linear behavior in inductor- or transformer-based passive balun components. The active-component balun circuit may be designed to have low noise, similar to passive baluns. The active-component balun circuit may also provide common-mode (CM) signal rejection, which helps in meeting in-band and out-of-band (OOB) emission standards with low-frequency and high-Frequency CM signal rejection.

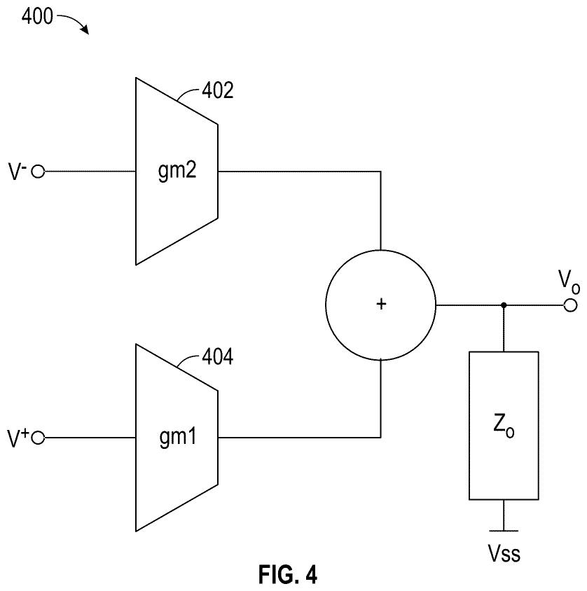

FIG. 4 illustrates an example active-component balun circuit 400 implemented with transimpedance (Gm) amplifiers, in accordance with certain aspects of the present disclosure. For example, the balun circuit 400 may include a Gm amplifier 402 and a Gm amplifier 404. The amplifier 404 receiving a first input voltage (e.g., positive input voltage v⁺) may have a first transimpedance (gm1), and the amplifier 402 receiving a second input voltage (e.g., negative input voltage v⁻) may have a second transimpedance (gm2). The outputs of the amplifiers 402, 404 may be coupled to provide a combined output signal to an output voltage (vₒ) node. As shown, an output impedance (Zₒ) may be coupled between the vₒ node and a reference potential node (e.g., electrical ground Vss). As described, the balun circuit 400 should provide CM signal rejection. In other words, when the positive and negative input voltages are equal in magnitude and phase, the balun circuit 400 should provide little to no gain. To achieve the CM signal rejection, the amplifiers 402, 404 may be implemented with the same gain but with opposite transfer functions. For instance, gm1 may be set to be equal to −gm2 or vice versa. In this manner, when the positive and negative input voltages are equal in a CM scenario, the output signals of the amplifiers 402, 404 may cancel out, providing zero gain at the output of the balun circuit 400.

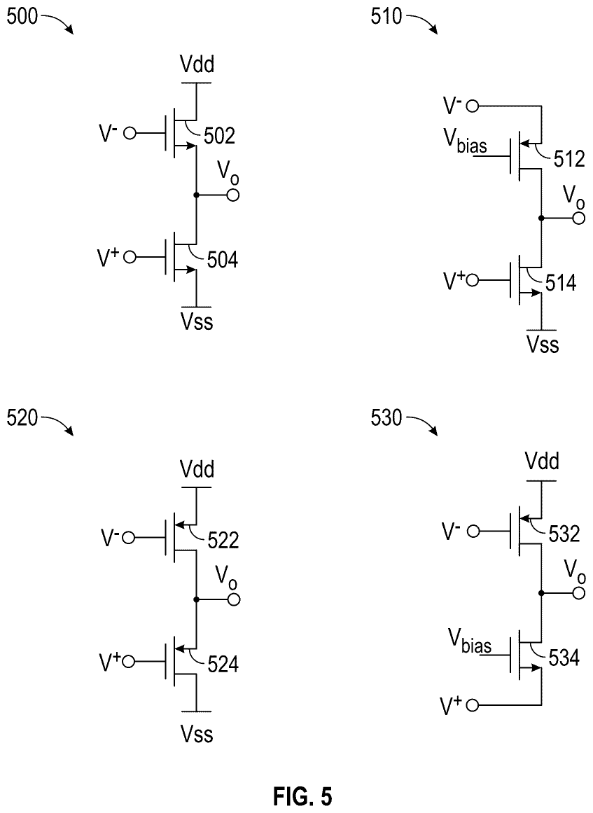

FIG. 5 illustrates example unipolar active-component balun configurations, in accordance with certain aspects of the present disclosure. A unipolar balun configuration refers to a configuration implemented with only n-type metal-oxide-semiconductor (NMOS) transistors or p-type metal-oxide-semiconductor (PMOS) transistors. A bipolar balun configuration refers to a configuration implemented with both NMOS and PMOS transistors. The active-component balun configuration 500 may include an NMOS transistor 502 with a drain coupled to a voltage rail (Vdd), a gate coupled to the negative input voltage node, and a source coupled to the output voltage node of the balun. The active-component balun configuration 500 may also include an NMOS transistor 504 with a drain coupled to the output voltage node of the balun, a source coupled to a reference potential node (Vss), and a gate coupled to the positive input voltage node. The NMOS transistor 502 effectively implements a source follower (SF) amplifier, and the NMOS transistor 504 effectively implements a common-source (CS) amplifier.

With an SF amplifier, the source voltage of the NMOS transistor 502 follows the gain voltage of the NMOS transistor 502, providing a positive transfer function with respect to the gate and source voltages (e.g., negative input voltage and output voltage) of the transistor 502. On the other hand, the CS amplifier implemented via transistor 504 has a negative transfer function with respect to the gate and drain voltages (e.g., positive input voltage and output voltage) of transistor 504. Thus, transistor 502 may be used to implement the amplifier 402 of FIG. 4, and transistor 504 may be used to implement the amplifier 404 of FIG. 4 or vice-versa to simultaneously provide CM signal rejection and differential signal gain.

An active-component balun configuration 510 may include a p-type metal-oxide-semiconductor (PMOS) transistor 512 with a source coupled to the negative input voltage node, a gate coupled to a bias voltage (Vbias) node, and a source coupled to the output voltage node of the balun. The configuration 510 may also include an NMOS transistor 514 with a drain coupled to the output voltage node, a source coupled to the reference potential node, and a gate coupled to the positive input voltage node. The transistor 512 may provide a positive transfer function with respect to the negative input voltage and the output voltage of the balun circuit and used to implement the amplifier 402. The transistor 514 may implement a CS amplifier providing a negative transfer function with respect to the positive input voltage and the output voltage of the balun. The transistor 514 may be used to implement the amplifier 404. The PMOS transistor 512 effectively implements a common-gate amplifier, and the PMOS transistor 514 effectively implements a common-source (CS) amplifier.

An active-component balun configuration 520 may include a PMOS transistor 522 with a drain coupled to the output voltage node of the balun, a source coupled to the voltage rail, and a gate coupled to the negative input voltage node. The configuration 520 also includes a PMOS transistor 524 with a source coupled to the output voltage node, a drain coupled to the reference potential node (Vss), and a gate coupled to the positive input voltage node. The PMOS transistor 524 implements a source follower (SF) amplifier, and the PMOS transistor 522 implements a common-source (CS) amplifier. Transistor 522 may be used to implement the amplifier 402 of FIG. 4, and transistor 524 may be used to implement the amplifier 404 of FIG. 4 to provide CM signal rejection.

An active-component balun configuration 530 may include a PMOS transistor 532 with a source coupled to the voltage rail (Vdd), a gate coupled to the negative input voltage node, and a drain coupled to the output voltage node. The active-component balun configuration 530 may also include an NMOS transistor 534 with a drain coupled to the output voltage node, a gate coupled to the Vbias node, and a source coupled to the positive input voltage node. The transistor 532 may be implemented as a CS amplifier and used as the amplifier 402, and the transistor 534 may be implemented as a common-gate amplifier and used to implement the amplifier 404.

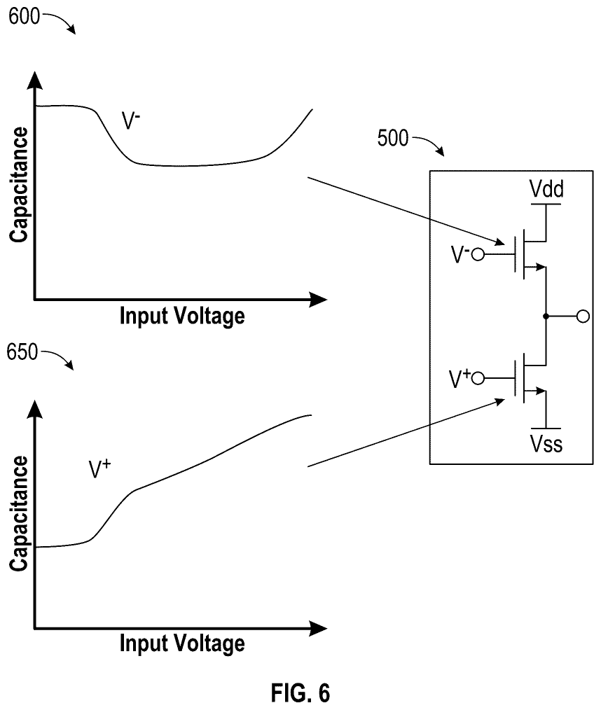

FIG. 6 illustrates graphs 600, 650 showing a mismatch in the input impedances (e.g., capacitances) of the positive and negative input voltage nodes of the active-component balun configuration 500. More specifically, each of the graphs 600, 650 show input capacitance as a function of peak-to-peak input voltage swing. As shown, at both the positive and negative input nodes of the active-component balun configuration 500, the input capacitance is non-linear with respect to changes in input voltage. This non-linear capacitance may result in amplitude modulation (AM) to phase modulation (PM) conversion that degrades the quality of the transmitter (e.g., in terms of various metrics such as adjacent channel leakage ratio (ACLR) and Error Vector Magnitude EVM). Certain aspects are directed towards techniques for increasing the input impedance linearity and balancing impedances between the balun circuit's input nodes.

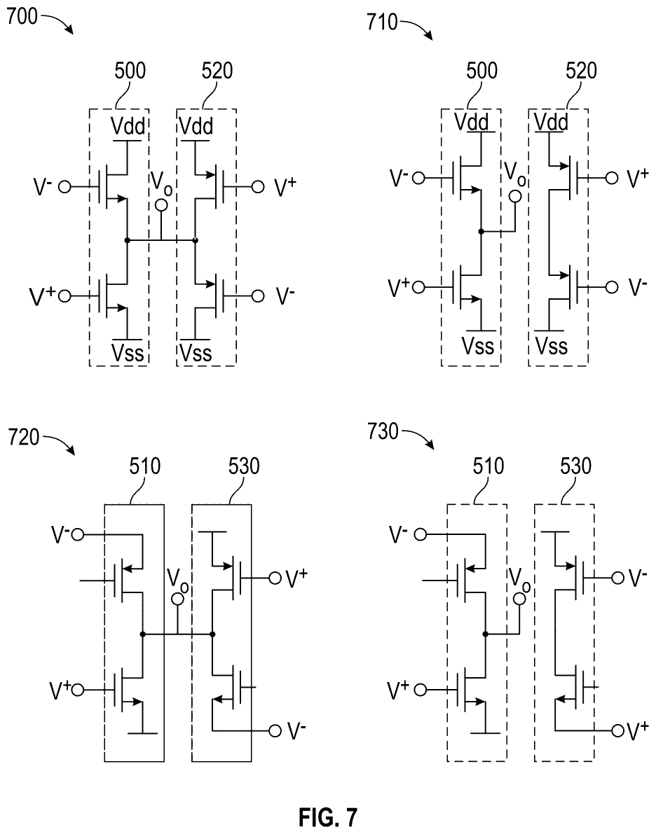

FIG. 7 illustrates examples of balun circuits implemented using a combination of active-component balun configurations described with respect to FIG. 5, in accordance with certain aspects of the present disclosure. The active-component balun circuit 700 may include the active-component balun configurations 500, 520 with outputs coupled (e.g., shorted) to the output voltage node. The active-component balun circuit 700 may provide increased input impedance linearity, greater output impedance linearity, and provide a high input impedance.

The active-component balun circuit 710 may include the active-component balun configuration 500 and a dummy version of the active-component balun configuration 520. In other words, the active-component balun configuration 520 may not be coupled to the output voltage node of the balun circuit 710, but included as part of the circuit 710 to improve impedance linearity or balancing of impedances between input nodes. The active-component balun circuit 710 may provide increased input impedance linearity, a more balanced input impedance than a single-pole active-component balun circuit. The active-component balun circuit 710 may also provide a high input impedance.

The active-component balun circuit 720 may include the active-component balun configuration 510 and the active-component balun configuration 530 with outputs coupled to the output voltage node of the balun circuit 720. The active-component balun circuit 720 may provide increased input and output impedance linearities.

The active-component balun circuit 730 may include the active-component balun configuration 510 and a dummy version of the active-component balun configuration 530. In other words, the active-component balun configuration 530 may not be coupled to the output voltage node of the active-component balun circuit 730. The active-component balun circuit 730 may provide increased input impedance linearity, a more balanced input impedance, and a lower input impedance than a single-pole balun circuit.

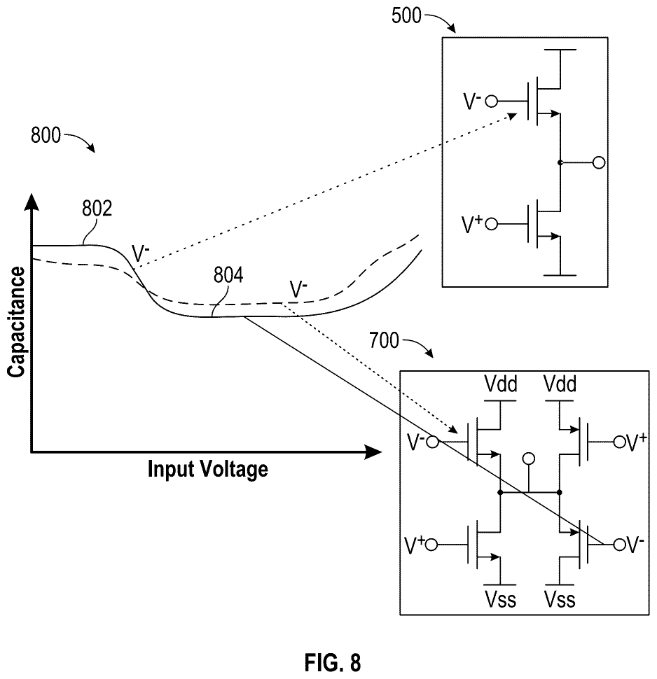

FIG. 8 illustrates a graph 800 showing the input capacitances at the negative input voltage nodes of the active-component balun configuration 500 and the active-component balun circuit 700, in accordance with certain aspects of the present disclosure. More specifically, the graph 800 shows the input capacitance (e.g., SF input capacitance) as a function of peak-to-peak input voltage swing. The curve 802 shows the input capacitance at the negative input voltage node of the active-component balun configuration 500 (e.g., a single-pole balun circuit), and the curve 804 shows the input capacitance at the negative input voltage node of the active-component balun circuit 700. As shown, by combining the active-component balun configuration 500 with the active-component balun configuration 520 to implement the balun circuit 700, the variation of the input capacitance driving the SF devices as a function of peak-to-peak input swing decreases which reduces the amplitude to phase modulation conversion, therefore improving the amplifier linearity.

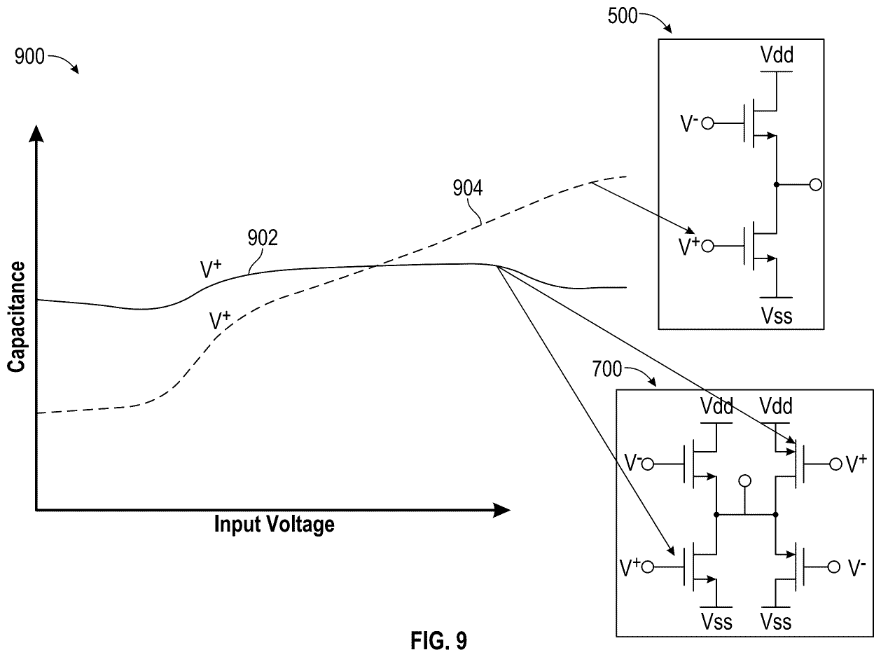

FIG. 9 illustrates a graph 900 showing the input capacitances at positive input voltage nodes of the active-component balun configuration 500 and the active-component balun circuit 700, in accordance with certain aspects of the present disclosure. More specifically, the graph 900 shows the input capacitance (e.g., CS input capacitance) as a function of peak-to-peak input voltage swing. The curve 902 shows the input capacitance at the positive input voltage node of the balun circuit 700 and the curve 904 shows the input capacitance at the positive input node of the active-component balun configuration 500. As shown, by combining the active-component balun configuration 500 with the active-component balun configuration 520 to implement the balun circuit 700, The variation of the input capacitance driving the CS devices over peak-2-peak input swing decreases which reduces the AM-2-PM conversion, therefore improving amplifier linearity.

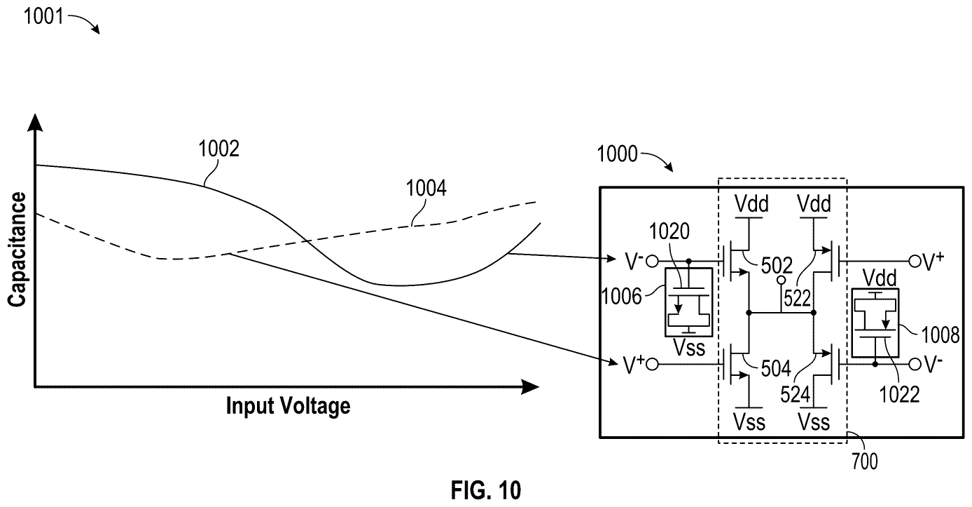

FIG. 10 illustrates a graph 1001 showing the input capacitance of an active-component balun circuit 1000 implemented with an input capacitive element, in accordance with certain aspects of the present disclosure. The balun circuit 1000 includes the active-component balun circuit 700, but with (i) a capacitive element 1006 coupled between the gate of transistor 502 and the reference potential node (Vss) and (ii) a capacitive element 1008 coupled between the gate of the transistor 524 and the voltage rail (Vdd).

The capacitive element 1006 may be implemented via the same type of transistor as transistor 502 (e.g., NMOS transistor), and the capacitive element 1008 may be implemented via the same type of transistor as transistor 524 (e.g., PMOS transistors). As shown, the capacitive element 1006 may be implemented via a transistor 1020 that has source and drain terminals coupled together. Similarly, the capacitive element 1008 may be implemented via a transistor 1022 having source and drain terminals coupled together. By adding the capacitive elements 1006, 1008, the input capacitance for the SF amplifiers (transistors 502, 524) may be more balanced compared to the CS amplifiers (transistors 504 and 522). Graph 1001 shows the input capacitance at the positive and negative input nodes of the balun circuit 1000. For example, the curve 1002 shows the combined input capacitance at the negative input node at the gates of transistor 502 and 504 of the balun circuit 1000, and the curve 1004 shows the combined input capacitance at the positive input node at the gates of transistor 504 and 522 of the balun circuit 1000. As shown, with the capacitive elements 1006, 1008, the input capacitances at the positive and negative input nodes are more linear and balanced

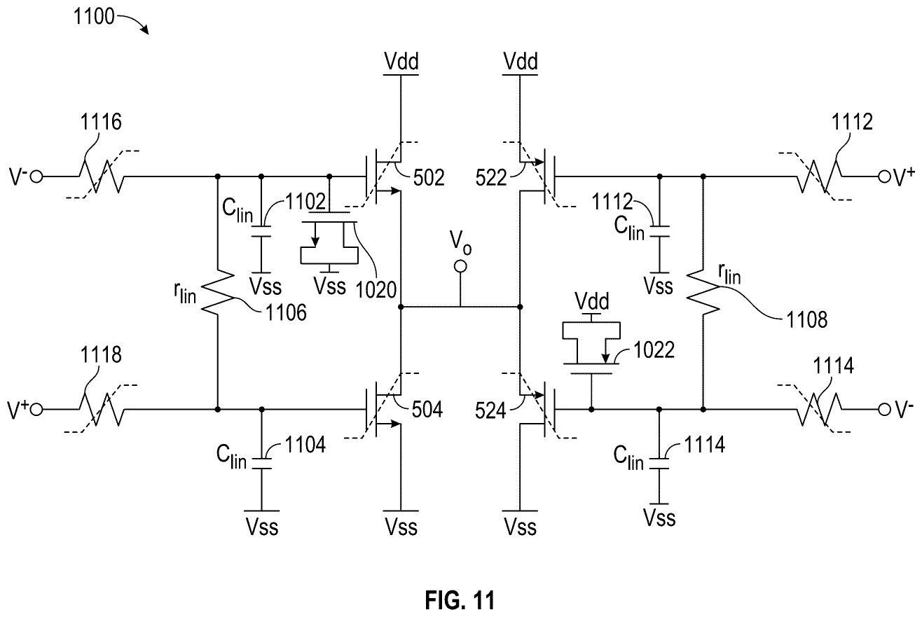

FIG. 11 illustrates a balun circuit 1100 implemented with linearization elements, in accordance with certain aspects of the present disclosure. To reduce the impact of both resistive and capacitive non-linear elements coupled or intrinsic to the balun circuit 1100, the balun circuit 1100 may be implemented with linear elements (e.g., in a shunt path coupled to the non-linear elements). For example, the resistive elements 1113, 1115, 1116, 1118 are non-linear elements representing the effect of a non-linear block (e.g., mixer 312 of FIG. 3) coupled to the input of the balun circuit 1100. In some aspects, a linear resistive element 1106 (labeled “rₗᵢₙ”) may be coupled between the gates of transistors 502, 504 and a linear resistive element 1108 (labeled “rₗᵢₙ”) may be coupled between the gates of transistors 522, 524. By adding the linear resistive elements, the impact of the balun circuit's non-linear input or intrinsic resistance on the transmitter's total linearity is reduced.

In some aspects, the balun circuit 1100 may include linear capacitive elements (e.g., labeled “Cₗᵢₙ”) to reduce the impact of a driving block or intrinsic nonlinear capacitance of the balun circuit 1100. For example, a capacitive element 1102 may be coupled between the gate of transistor 502 and the reference potential node (Vss), a capacitive element 1104 may be coupled between the gate of transistor 504 and the reference potential node, a capacitive element 1112 may be coupled between the gate of transistor 522 and the reference potential node, and a capacitive element 1114 may be coupled between the gate of transistor 524 and the reference potential node. Adding the linear capacitive elements reduces the ratio of the nonlinear to linear capacitance thus reducing the amplitude to phase modulation conversion and consequently improving the ACLR of the transmitter.

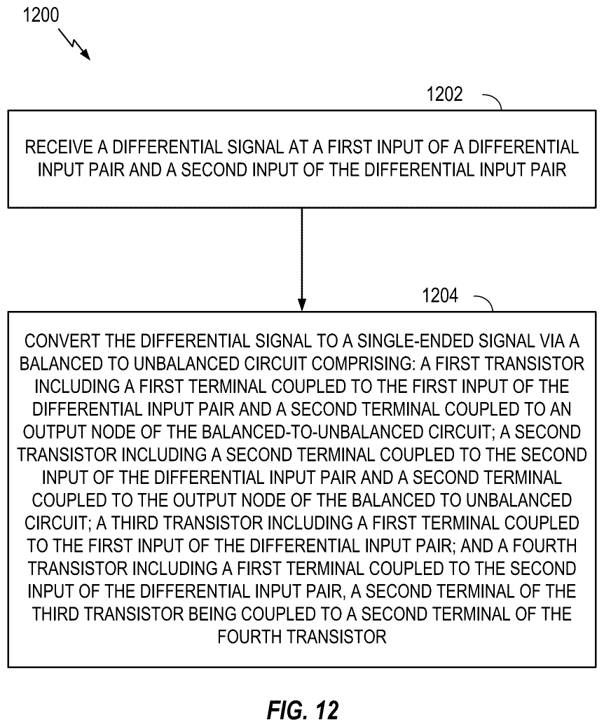

FIG. 12 is a flow diagram illustrating example operations 1200 for differential-to-single-ended signal conversion. The operations 1200 may be performed using a balun circuit, such as the balun circuits 700, 710, 720, 730, 1000, or 1100.

At block 1202, the balun circuit receives a differential signal (e.g., positive input and negative input voltages labeled “v⁺” and “v⁻”) at a first input of a differential input pair and a second input of the differential input pair. At block 1204, the balun circuit converts the differential signal to a single-ended signal.

The balun circuit may include: a first transistor (e.g., transistor 502) including a first terminal coupled to the first input of the differential input pair and a second terminal coupled to an output node (e.g., vₒ node) of the balanced-to-unbalanced circuit; a second transistor (e.g., transistor 504) including a second terminal coupled to the second input of the differential input pair and a second terminal coupled to the output node of the balanced-to-unbalanced circuit; a third transistor (e.g., transistor 522) including a first terminal coupled to the first input of the differential input pair; and a fourth transistor (e.g., transistor 524) including a first terminal coupled to the second input of the differential input pair, a second terminal of the third transistor being coupled to a second terminal of the fourth transistor. In some aspects, a third terminal of the first transistor is coupled to a voltage rail (e.g., Vdd), and a third terminal of the second transistor is coupled to a reference potential node (e.g., Vss). The third terminal of the first transistor may be a drain terminal of the first transistor, and the third terminal of the second transistor may be a source terminal of the second transistor.

In some aspects, the second terminals of the third transistor and the fourth transistor are coupled to the output node, as shown with regards to the balun circuit.

In some aspects, the first terminal of the first transistor comprises a gate of the first transistor coupled to the first input, and the first terminal of the second transistor comprises a gate of the second transistor coupled to the first input. In some aspects, the first transistor and the second transistor are NMOS transistors, and the third transistor and the fourth transistor comprise PMOS transistors.

In some implementations (e.g., such as for balun circuit 720), the second transistor and the fourth transistor are NMOS transistors, and the first transistor and the third transistor are PMOS transistors. In some cases, the first terminal of the first transistor may include a source of the first transistor coupled to the first input, and the first terminal of the fourth transistor may include a source of the fourth transistor coupled to the first input.

In some aspects, the balun circuit may include: a first capacitive element (e.g., capacitive element 1006) coupled between the first terminal of the first transistor and a reference potential node and a second capacitive element (e.g., capacitive element 1008) coupled between the first terminal of the fourth transistor and a voltage rail. The first capacitive element may include a fifth transistor (e.g., transistor 1020) with a source coupled to a drain of the fifth transistor, and the second capacitive element may include a sixth transistor (e.g., transistor 1022) with a source coupled to a drain of the sixth transistor.

In some aspects, the balun circuit also includes a first capacitive element (e.g., capacitive element 1102) coupled between the first terminal of the first transistor and a reference potential node and a second capacitive element (e.g., capacitive element 1104) coupled between the first terminal of the second transistor and the reference potential node. The balun circuit may also include a third capacitive element (e.g., capacitive element 1112) coupled between the first terminal of the third transistor and the reference potential node and a fourth capacitive element (e.g., capacitive element 1114) coupled between the first terminal of the fourth transistor and the reference potential node.

In some aspects, the balun circuit includes a first resistive element (e.g., resistive element 1106) coupled between the first terminals of the first transistor and the second transistor. The balun circuit may also include a second resistive element (e.g., resistive element 1108) coupled between the first terminals of the third transistor and the fourth transistor.

### EXAMPLE ASPECTS

### Aspect 1

An apparatus for differential-to-single-ended signal conversion, comprising: a first transistor including a first terminal coupled to a first input of a differential input pair of the apparatus and a second terminal coupled to an output node of the apparatus; a second transistor including a second terminal coupled to a second input of the differential input pair and a second terminal coupled to the output node of the apparatus; a third transistor including a first terminal coupled to the first input of the differential input pair; and a fourth transistor including a first terminal coupled to the second input of the differential input pair, a second terminal of the third transistor being coupled to a second terminal of the fourth transistor.

### Aspect 2

The apparatus of Aspect 1, wherein: a third terminal of the first transistor is coupled to a voltage rail; and a third terminal of the second transistor is coupled to a reference potential node.

### Aspect 3

The apparatus of Aspect 2, wherein: the third terminal of the first transistor is a drain terminal of the first transistor; and the third terminal of the second transistor is a source terminal of the second transistor.

### Aspect 4

The apparatus according to any of Aspects 1-3, wherein the second terminal of the third transistor and the second terminal of the fourth transistor are coupled to the output node.

### Aspect 5

The apparatus according to any of Aspects 1-4, wherein: the first terminal of the first transistor comprises a gate of the first transistor coupled to the first input; and the first terminal of the second transistor comprises a gate of the second transistor coupled to the first input.

### Aspect 6

The apparatus according to any of Aspects 1-5, wherein: the first transistor and the second transistor comprise n-type metal-oxide-semiconductor (NMOS) transistors; and the third transistor and the fourth transistor comprise p-type metal-oxide-semiconductor (PMOS) transistors.

### Aspect 7

The apparatus according to any of Aspects 1-6, wherein: the second transistor and the fourth transistor comprise n-type metal-oxide-semiconductor (NMOS) transistors; and the first transistor and the third transistor comprise p-type metal-oxide-semiconductor (PMOS) transistors.

### Aspect 8

The apparatus according to any of Aspects 1-7, wherein: the first terminal of the first transistor comprises a source terminal of the first transistor coupled to the first input; and the first terminal of the fourth transistor comprises a source terminal of the fourth transistor coupled to the first input.

### Aspect 9

The apparatus according to any of Aspects 1-8, further comprising: a first capacitive element coupled between the first terminal of the first transistor and a reference potential node; and a second capacitive element coupled between the first terminal of the fourth transistor and a voltage rail.

### Aspect 10

The apparatus of Aspect 9, wherein: the first capacitive element includes a fifth transistor with a source coupled to a drain of the fifth transistor; and the second capacitive element includes a sixth transistor with a source coupled to a drain of the sixth transistor.

### Aspect 11

The apparatus of Aspect 10, wherein: the first transistor and the fifth transistor are n-type metal-oxide-semiconductor (NMOS) transistors; and the fourth transistor and the sixth transistor are p-type metal-oxide-semiconductor (PMOS) transistors.

### Aspect 12

The apparatus according to any of Aspects 1-11, further comprising: a first capacitive element coupled between the first terminal of the first transistor and a reference potential node; and a second capacitive element coupled between the first terminal of the second transistor and the reference potential node.

### Aspect 13

The apparatus of Aspect 12, further comprising: a third capacitive element coupled between the first terminal of the third transistor and the reference potential node; and a fourth capacitive element coupled between the first terminal of the fourth transistor and the reference potential node.

### Aspect 14

The apparatus according to any of Aspects 1-13, further comprising a first resistive element coupled between the first terminal of the first transistor and the first terminal of the second transistor.

### Aspect 15

The apparatus of Aspect 14, further comprising a second resistive element coupled between the first terminal of the third transistor and the first terminal of the fourth transistor.

### Aspect 16

A method for differential-to-single-ended signal conversion, comprising: receiving a differential signal at a first input of a differential input pair and a second input of the differential input pair; and converting the differential signal to a single-ended signal via a balanced-to-unbalanced circuit comprising: a first transistor including a first terminal coupled to the first input of the differential input pair and a second terminal coupled to an output node of the balanced-to-unbalanced circuit; a second transistor including a second terminal coupled to the second input of the differential input pair and a second terminal coupled to the output node of the balanced-to-unbalanced circuit; a third transistor including a first terminal coupled to the first input of the differential input pair; and a fourth transistor including a first terminal coupled to the second input of the differential input pair, a second terminal of the third transistor being coupled to a second terminal of the fourth transistor.

### Aspect 17

The method of Aspect 16, wherein: a third terminal of the first transistor is coupled to a voltage rail; and a third terminal of the second transistor is coupled to a reference potential node.

### Aspect 18

The method of Aspect 17, wherein: the third terminal of the first transistor is a drain terminal of the first transistor; and the third terminal of the second transistor is a source terminal of the second transistor.

### Aspect 19

The method according to any of Aspects 16-18, wherein the second terminal of the third transistor and the second terminal of the fourth transistor are coupled to the output node.

### Aspect 20

A transmitter comprising: a mixer; and an active-component balanced-to-unbalanced (balun) circuit coupled to the mixer and including: a first transistor including a first terminal coupled to a first input of a differential input pair of the active-component balun circuit and a second terminal coupled to an output node of the active-component balun circuit; a second transistor including a second terminal coupled to a second input of the differential input pair and a second terminal coupled to the output node of the active-component balun circuit; a third transistor including a first terminal coupled to the first input of the differential input pair; and a fourth transistor including a first terminal coupled to the second input of the differential input pair, a second terminal of the third transistor being coupled to a second terminal of the fourth transistor.

### Additional Considerations

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. An apparatus for differential-to-single-ended signal conversion, comprising:
a first transistor including a first terminal coupled to a first input of a differential input pair of the apparatus and a second terminal coupled to an output node of the apparatus;
a second transistor including a second terminal coupled to a second input of the differential input pair and a second terminal coupled to the output node of the apparatus;
a third transistor including a first terminal coupled to the first input of the differential input pair; and
a fourth transistor including a first terminal coupled to the second input of the differential input pair, a second terminal of the third transistor being coupled to a second terminal of the fourth transistor.

2. The apparatus of claim 1, wherein:
a third terminal of the first transistor is coupled to a voltage rail; and
a third terminal of the second transistor is coupled to a reference potential node.

3. The apparatus of claim 2, wherein:
the third terminal of the first transistor is a drain terminal of the first transistor; and
the third terminal of the second transistor is a source terminal of the second transistor.

4. The apparatus of claim 1, wherein the second terminal of the third transistor and the second terminal of the fourth transistor are coupled to the output node.

5. The apparatus of claim 1, wherein:
the first terminal of the first transistor comprises a gate of the first transistor coupled to the first input; and
the first terminal of the second transistor comprises a gate of the second transistor coupled to the first input.

6. The apparatus of claim 1, wherein:
the first transistor and the second transistor comprise n-type metal-oxide-semiconductor (NMOS) transistors; and
the third transistor and the fourth transistor comprise p-type metal-oxide-semiconductor (PMOS) transistors.

7. The apparatus of claim 1, wherein:
the second transistor and the fourth transistor comprise n-type metal-oxide-semiconductor (NMOS) transistors; and
the first transistor and the third transistor comprise p-type metal-oxide-semiconductor (PMOS) transistors.

8. The apparatus of claim 1, wherein:
the first terminal of the first transistor comprises a source terminal of the first transistor coupled to the first input; and
the first terminal of the fourth transistor comprises a source terminal of the fourth transistor coupled to the first input.

9. The apparatus of claim 1, further comprising:
a first capacitive element coupled between the first terminal of the first transistor and a reference potential node; and
a second capacitive element coupled between the first terminal of the fourth transistor and a voltage rail.

10. The apparatus of claim 9, wherein:
the first capacitive element includes a fifth transistor with a source coupled to a drain of the fifth transistor; and
the second capacitive element includes a sixth transistor with a source coupled to a drain of the sixth transistor.

11. The apparatus of claim 10, wherein:
the first transistor and the fifth transistor are n-type metal-oxide-semiconductor (NMOS) transistors; and
the fourth transistor and the sixth transistor are p-type metal-oxide-semiconductor (PMOS) transistors.

12. The apparatus of claim 1, further comprising:
a first capacitive element coupled between the first terminal of the first transistor and a reference potential node; and
a second capacitive element coupled between the first terminal of the second transistor and the reference potential node.

13. The apparatus of claim 12, further comprising:
a third capacitive element coupled between the first terminal of the third transistor and the reference potential node; and
a fourth capacitive element coupled between the first terminal of the fourth transistor and the reference potential node.

14. The apparatus of claim 1, further comprising a first resistive element coupled between the first terminal of the first transistor and the first terminal of the second transistor.

15. The apparatus of claim 14, further comprising a second resistive element coupled between the first terminal of the third transistor and the first terminal of the fourth transistor.

16. A method for differential-to-single-ended signal conversion, comprising:
receiving a differential signal at a first input of a differential input pair and a second input of the differential input pair; and
converting the differential signal to a single-ended signal via a balanced-to-unbalanced circuit comprising:
a first transistor including a first terminal coupled to the first input of the differential input pair and a second terminal coupled to an output node of the balanced-to-unbalanced circuit;
a second transistor including a second terminal coupled to the second input of the differential input pair and a second terminal coupled to the output node of the balanced-to-unbalanced circuit;
a third transistor including a first terminal coupled to the first input of the differential input pair; and
a fourth transistor including a first terminal coupled to the second input of the differential input pair, a second terminal of the third transistor being coupled to a second terminal of the fourth transistor.

17. The method of claim 16, wherein:
a third terminal of the first transistor is coupled to a voltage rail; and
a third terminal of the second transistor is coupled to a reference potential node.

18. The method of claim 17, wherein:
the third terminal of the first transistor is a drain terminal of the first transistor; and
the third terminal of the second transistor is a source terminal of the second transistor.

19. The method of claim 16, wherein the second terminal of the third transistor and the second terminal of the fourth transistor are coupled to the output node.

20. A transmitter comprising:
a mixer; and
an active-component balanced-to-unbalanced (balun) circuit coupled to the mixer and including:
a first transistor including a first terminal coupled to a first input of a differential input pair of the active-component balun circuit and a second terminal coupled to an output node of the active-component balun circuit;
a second transistor including a second terminal coupled to a second input of the differential input pair and a second terminal coupled to the output node of the active-component balun circuit;
a third transistor including a first terminal coupled to the first input of the differential input pair; and
a fourth transistor including a first terminal coupled to the second input of the differential input pair, a second terminal of the third transistor being coupled to a second terminal of the fourth transistor.
